(19) United States
(12) Patent Application Publication
(10) Pub. No.: US 2007/0243317 A1
(43) Pub. Date: Oct. 18, 2007

(54) Thermal Processing System and Configurable Vertical Chamber

(76) Inventors: Dale R. Du Bois, Los Gatos, CA (US); Jamie H. Nam, Scotts Valley, CA (US); Craig Wildman, Sunnyvale, CA (US); Taiquing Qiu, Los Gatos, CA (US); Jeffrey M. Kowalski, Aptos, CA (US)

Correspondence Address: DORSEY & WHITNEY LLP, 555 CALIFORNIA STREET, SUITE 1000, SUITE 1000, SAN FRANCISCO, CA, 94104, US

(21) Appl. No.: 10/521,619

(22) PCT Filed: Jul. 10, 2003
(86) PCT No.: PCT/US03/21575

§ 371 Date: Feb. 26, 2007

Related U.S. Application Data
(60) Provisional application No. 60/396,536, filed on Jul. 15, 2002.
(60) Provisional application No. 60/428,526, filed on Nov. 22, 2002.

(51) Int. Cl. C23C 16/00

(52) U.S. Cl. 427/98.9; 118/725

(57) ABSTRACT

An apparatus (100) and method are provided for thermally processing substrates (108) held in a carrier (106). The apparatus (100) includes a vessel (101) having a top (134), side (136) and bottom (138), and a heat source (110) with heating elements (112-1, 112-2, 112-3) proximal thereto. The vessel (101) is sized to enclose a volume substantially no larger than necessary to accommodate the carrier (106), and to provide an isothermal process zone (128) extending throughout. In one embodiment, the bottom wall (138) includes a movable pedestal (140) with a bottom heating element therein (112-1), and the pedestal can be lowered and raised to insert the carrier (106) into the vessel (101). The apparatus (100) can include a movable shield (146) that is inserted between the pedestal (140) and the carrier (106) to shield the substrates (108) from the heating element (112-1) and to maintain pedestal temperature. A magnetically coupled repositioning system (162) repositions the carrier (106) during processing of the substrates (108) without use of a movable feedthrough into the volume enclosed by the vessel (101), and without moving the bottom heating element (112-1) in the pedestal (140).

### CROSS REFERENCE TO RELATED APPLICATIONS

The present application claims the benefit of and priority from commonly assigned U.S. Provisional Patent Application Ser. Nos. 60/396,536, entitled Thermal Processing System, and filed Jul. 15, 2002, and 60/428,526, entitled Thermal Processing System and Method for Using the Same, and filed Nov. 22, 2002, both of which are incorporated herein by reference in their entirety.

### TECHNICAL FIELD

The present invention relates generally to systems and methods for heat-treating objects, such as substrates. More specifically, the present invention relates to an apparatus and method for heat treating, annealing, and depositing layers of material on or removing layers of material from a semiconductor wafer or substrate.

### BACKGROUND

Thermal processing apparatuses are commonly used in the manufacture of integrated circuits (ICs) or semiconductor devices from semiconductor substrates or wafers. Thermal processing of semiconductor wafers include, for example, heat treating, annealing, diffusion or driving of dopant material, deposition or growth of layers of material, and etching or removal of material from the substrate. These processes often call for the wafer to be heated to a temperature as high as 1300° C. and as low as 300° C. before and during the process, and that one or more fluids, such as a process gas or reactant, be delivered to the wafer. Moreover, these processes typically require that the wafer be maintained at a uniform temperature throughout the process, despite variations in the temperature of the process gas or the rate at which it is introduced into the process chamber.

A conventional thermal processing apparatus typically consists of a voluminous process chamber positioned in or surrounded by a furnace. Substrates to be thermally processed are sealed in the process chamber, which is then heated by the furnace to a desired temperature at which the processing is performed. For many processes, such as Chemical Vapor Deposition (CVD), the sealed process chamber is first evacuated, and once the process chamber has reached the desired temperature a reactive or process gases are introduced to form or deposit reactant species on the substrates.

In the past, thermal processing apparatus typically and in particular vertical thermal processing apparatuses, required guard heaters disposed adjacent to sidewalls of the process chamber above and below the process zone in which product wafers were processed. This arrangement is undesirable since it entails a larger chamber volume that must be pumped down, filled with process gas or vapor, and backfilled or purged, resulting in increased processing time. Moreover, this configuration takes up a tremendous amount of space and power due to a poor view factor of the wafers from the heaters.

Other problems with conventional thermal processing apparatuses include the considerable time required both before processing to ramp up the temperature of the process chamber and the wafer to be treated, and the time required after processing to ramp down the temperature. Furthermore, additional time is often required to ensure the temperature of the process chamber has stabilized uniformly at the desired temperature before processing can begin. While the actual time required for processing of the wafers may be half hour or less, pre- and post-processing times typically take 1 to 3 hours or longer. Thus, the time required to quickly ramp up and/or down the temperature of the process chamber to a uniform temperature significantly limits the throughput of the conventional thermal processing apparatus.

A fundamental reason for the relatively long ramp up and ramp down times is the thermal mass of the process chamber and/or furnace in conventional thermal processing apparatuses, which must be heated or cooled prior to effectively heating or cooling the wafer.

A common approach to minimizing or offsetting this limitation on throughput of conventional thermal processing apparatus has been to increase the number of wafers capable of being processed in a single cycle or run. Simultaneous processing of a large number of wafers helps to maximize the effective throughput of the apparatus by reducing the effective processing time on a per wafer basis. However, this approach also increases the magnitude of the risk should something go wrong during processing. That is a larger number of wafers could be destroyed or damaged by a single failure, for example, if there was an equipment or process failure during a single processing cycle. This is particularly a concern with larger wafer sizes and more complex integrated circuits where a single wafer could be valued at from $1,000 to $10,000 depending on the stage of processing.

Another problem with this solution is that increasing the size of the process chamber to accommodate a larger number of wafers increases the thermal mass effects of the process chamber, thereby reducing the rate at which the wafer can be heated or cooled. Moreover, larger process chambers processing larger batches of wafers leads to or compounds a first-in-last-out syndrome in which the first wafers loaded into the chamber are also the last wafers removed, resulting in these wafers being exposed to elevated temperatures for longer periods and reducing uniformity across the batch of wafers.

Another problem with the above approach is that systems and apparatuses used for many of the processes before and after thermal processing are not amenable to simultaneous processing of large numbers of wafers. Thus, thermal processing of large batches or large numbers wafers, while increasing the throughput of the thermal processing apparatus, can do little to improve the overall throughput of the semiconductor fabrication facility and may actually reduce it by requiring wafers to accumulate ahead of the thermal processing apparatus or causing wafers to bottleneck at other systems and apparatuses downstream therefrom.

An alternative to the conventional thermal processing apparatus described above, are rapid thermal processing (RTP) systems that have been developed for rapidly thermal processing of wafers. Conventional RTP systems generally use high intensity lamps to selectively heat a single wafer or small number of wafers within a small, transparent, usually quartz, process chamber. RTP systems minimize or eliminate the thermal mass effects of the process chamber, and since the lamps have very low thermal mass, the wafer can be heated and cooled rapidly by instantly turning the lamps on or off.

Unfortunately, conventional RTP systems have significant shortcomings including the placement of the lamps, which in the past were arranged in zones or banks each consisting of a number of lamps adjacent to sidewalls of the process chamber. This configuration is problematic because it takes up a tremendous amount of space and power in order to be effective due to their poor view factor, all of which are at a premium in the latest generation of semiconductor processing equipment.

Another problem with conventional RTP systems is their inability to provide uniform temperature distribution across multiple wafers within a single batch of wafers and even across a single wafer. There are several reasons for this non-uniform temperature distribution including (i) a poor view factor of one or more of the wafers by one or more of the lamps, and (ii) variation in output power from the lamps.

Moreover, failure or variation in the output of a single lamp can adversely affect the temperature distribution across the wafer. Because of this in most lamp-based systems, the wafer or wafers are rotated to ensure that the temperature non-uniformity due to the variation in lamp output is not transferred to the wafer during processing. However, the moving parts required to rotate the wafer, particularly the rotating feedthrough into the process chamber, adds to the cost and complexity of the system, and reduces the overall reliability thereof.

Yet another troublesome area for RTP systems is in maintaining uniform temperature distribution across the outer edges and the center of the wafer. Most conventional RTP systems have no adequate means to adjust for this type of temperature non-uniformity. As a result, transient temperature fluctuations occur across the surface of the wafer that can cause the formation of slip dislocations in the wafer at high temperatures, unless a black body susceptor is used that is larger in diameter than the wafer.

Conventional lamp-based RTP systems have other drawbacks. For example, there are no adequate means for providing uniform power distribution and temperature uniformity during transient periods, such as when the lamps are powered on and off, unless phase angle control is used which produces electrical noise. Repeatability of performance is also usually a drawback of lamp-based systems, since each lamp tends to perform differently as it ages. Replacing lamps can also be costly and time consuming, especially when one considers that a given lamp system may have upwards of 180 lamps. The power requirement may also be costly, since the lamps may have a peak power consumption of about 250 kWatts.

Accordingly, there is a need for an apparatus and method for quickly and uniformly heating a batch of one or more substrates to a desired temperature across the surface of each substrate in the batch of during thermal processing.

### SUMMARY

The present invention provides a solution to these and other problems, and offers other advantages over the prior art.

The present invention provides an apparatus and method for isothermally heating work pieces, such as semiconductor substrates or wafers, for performing processes such as annealing, diffusion or driving of dopant material, deposition or growth of layers of material, and etching or removal of material from the wafer.

A thermal processing apparatus is provided for processing substrates held in a carrier at high or elevated temperatures. The apparatus includes a process chamber having a top wall, a side wall and a bottom wall, and a heating source having a number of heating elements proximal to the top wall, the side wall and the bottom wall of the process chamber to provide an isothermal environment in a process zone in which the carrier is positioned to thermally process the substrates. According to one aspect, the dimensions of the process chamber are selected to enclose a volume substantially no larger than a volume necessary to accommodate the carrier, and the process zone extends substantially throughout the process chamber. Preferably, the process chamber has dimensions selected to enclose a volume substantially no larger than 125% of that necessary to accommodate the carrier. More preferably, the apparatus further includes a pumping system to evacuate the process chamber prior to processing pressure and a purge system to backfill the process chamber after processing is complete, and the dimensions of the process chamber are selected to provide both a rapid evacuation and a rapid backfilling of the process chamber.

According to another aspect of the invention, the bottom wall of the process chamber includes a movable pedestal having at least one heating element therein, and the movable pedestal is adapted to be lowered and raised to enable the carrier with the substrates to be inserted into and removed from the process chamber. In one embodiment, the apparatus further includes a removable thermal shield adapted to be inserted between heating element in the pedestal and the substrates held the carrier. The thermal shield is adapted to reflect thermal energy from the heating element in the pedestal back to the pedestal, and to shield the substrates on the carrier from thermal energy from the heating element in the pedestal. In one version of this embodiment, the apparatus further includes a shutter adapted to be moved into place above the carrier to isolate the process chamber when the pedestal is in a lowered position. Where the apparatus includes a pumping system to evacuate the process chamber, and the shutter can be adapted to seal with the process chamber, thereby enabling the pumping system to evacuate the process chamber when the pedestal is in the lowered position.

In yet another embodiment, the apparatus further includes a magnetically coupled repositioning system that repositions the carrier during thermal processing of the substrates. Preferably, the mechanical energy used to reposition the carrier is magnetically coupled through the pedestal to the carrier without use of a movable feedthrough into the process chamber, and substantially without moving the heating element in the pedestal. More preferably, the magnetically coupled repositioning system is a magnetically coupled rotation system that rotates the carrier within the process zone during thermal processing of the substrates.

According to yet another aspect of the invention, the apparatus further includes a liner separating the carrier from the top wall and the side wall of the process chamber, and a distributive or cross-flow injection system to direct flow of a fluid across surfaces of each of the substrates held in the carrier. The cross-flow injection system generally includes a cross-flow injector having a number of injection ports positioned relative to substrates held in the carrier, and through which the fluid is introduced on one side of the number of substrates. A number of exhaust ports in the liner positioned relative to the substrates held in the carrier cause the fluid to flow across the surfaces of the substrates. Fluids introduced by the cross-flow injection system can include process gas or vapor, and inert purge gases or vapor used for purging or backfilling the chamber or for cooling the substrates therein.

### BRIEF DESCRIPTION OF THE DRAWINGS

These and various other features and advantages of the present invention will be apparent upon reading of the following detailed description in conjunction with the accompanying drawings and the appended claims provided below, where:

FIG. 1 is a cross-sectional view of a thermal processing apparatus having a pedestal heater for providing an isothermal control volume according to an embodiment of the present invention, employing conventional up-flow configuration;

FIG. 2 is a perspective view of an alternative embodiment a base-plate useful in the thermal processing apparatus shown in FIG. 1;

FIG. 3 is a cross-sectional view of a portion of a thermal processing apparatus having a pedestal heater and a thermal shield according to an embodiment of the present invention;

FIG. 4 is a diagrammatic illustration of the pedestal heater and thermal shield of FIG. 3 according to an embodiment of the present invention;

FIG. 5 is a diagrammatic illustration of an embodiment of the thermal shield having a top layer of material with a high absorptivity and a lower layer of material with a high reflectivity according to present invention;

FIG. 6 is a diagrammatic illustration of another embodiment of the thermal shield having a cooling channel according to present invention;

FIG. 7 is a perspective view of an embodiment of a thermal shield and an actuator according to present invention;

FIG. 8 is a cross-sectional view of a portion of a thermal processing apparatus having a shutter according to an embodiment of the present invention;

FIG. 9 is a cross-sectional view of a process chamber having a pedestal heater and a magnetically coupled wafer rotation system according to an embodiment of the present invention;

FIG. 10 is a cross-sectional view of a thermal processing apparatus having a cross-flow injector system according to an embodiment of the present invention;

FIG. 11 is a cross-sectional side view of a portion of the thermal processing apparatus of FIG. 10 showing positions of injector orifices in relation to the liner and of exhaust slots in relation to the wafers according to an embodiment of the present invention;

FIG. 12 is a plan view of a portion of the thermal processing apparatus of FIG. 10 taken along the line A-A of FIG. 10 showing gas flow from orifices of a primary and a secondary injector across a wafer and to an exhaust port according to an embodiment of the present invention;

FIG. 13 is a plan view of a portion of the thermal processing apparatus of FIG. 10 taken along the line A-A of FIG. 10 showing gas flow from orifices of a primary and a secondary injector across a wafer and to an exhaust port according to another embodiment of the present invention;

FIG. 14 is a plan view of a portion of the thermal processing apparatus of FIG. 10 taken along the line A-A of FIG. 10 showing gas flow from orifices of a primary and a secondary injector across a wafer and to an exhaust port according to yet another embodiment of the present invention;

FIG. 15 is a plan view of a portion of the thermal processing apparatus of FIG. 10 taken along the line A-A of FIG. 10 showing gas flow from orifices of a primary and a secondary injector across a wafer and to an exhaust port according to still another embodiment of the present invention;

FIG. 16 is a cross-sectional view of a thermal processing apparatus having an alternative up-flow injector system according to an embodiment of the present invention;

FIG. 17 is a cross-sectional view of a thermal processing apparatus having an alternative down-flow injector system according to an embodiment of the present invention;

FIG. 18 is flowchart showing an embodiment of a process for thermally processing a batch of wafers according to an embodiment of the present invention whereby each wafer of the batch of wafers is quickly and uniformly heated to the desired temperature; and

FIG. 19 is flowchart showing another embodiment of a process for thermally processing a batch of wafers according to an embodiment of the present invention whereby each wafer of the batch of wafers is quickly and uniformly heated to the desired temperature.

### DETAILED DESCRIPTION

The present invention is directed to an apparatus and method for processing a relatively small number or mini-batch of one or more work pieces, such as semiconductor substrates or wafers, held in a carrier, such as a cassette or boat, that provides reduced processing cycle times and improved process uniformity.

As used herein the term “mini-batch” means a number of wafers less than the hundreds of wafers found in the typical batch systems, and preferably in the range of from one to about fifty-three semiconductor wafers or wafers, of which from one to fifty are product wafers and the remainder are non-product wafers used for monitoring purposes and as baffle wafers.

By thermal processing it is meant processes that in which the work piece or wafer is heated to a desired temperature which is typically in the range of about 350° C. to 1300° C. Thermal processing of semiconductor wafers can include, for example, heat treating, annealing, diffusion or driving of dopant material, deposition or growth of layers of material, such as chemical vapor deposition or CVD, and etching or removal of material from the wafers.

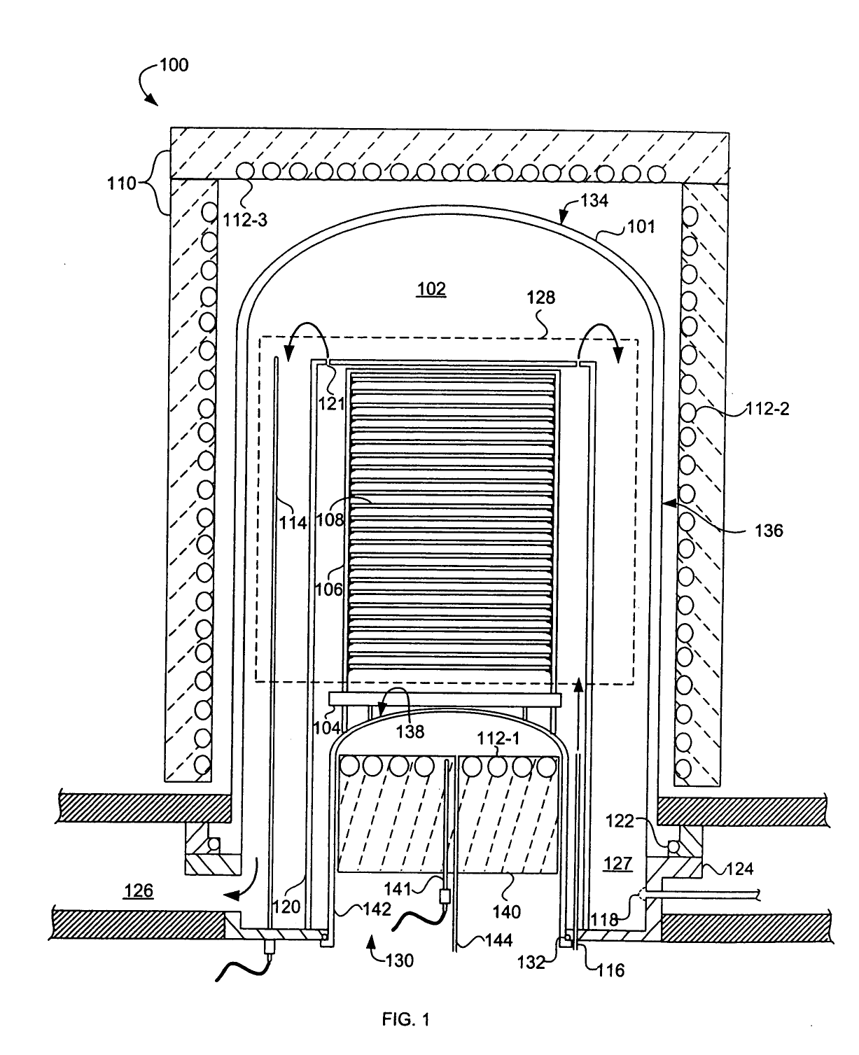

A thermal processing apparatus according to an embodiment will now be described with reference to FIG. 1. For purposes of clarity, many of the details of thermal processing apparatuses that are widely known and are widely known to a person of skill in the art have been omitted. Such detail is described in more detail in, for example, commonly assigned U.S. Pat. No. 4,770,590, which is incorporated herein by reference.

FIG. 1 is a cross-sectional view of an embodiment of a thermal processing apparatus for thermally processing a batch of semiconductor wafers. As shown, the thermal processing apparatus 100, generally includes a vessel 101 that encloses a volume to form a process chamber 102 having a support 104 adapted for receiving a carrier or boat 106 with a batch of wafers 108 held therein, and heat source or furnace 110 having a number of heating elements 112-1, 112-2 and 112-3 (referred to collectively hereinafter as heating elements 112) for raising a temperature of the wafers to the desired temperature for thermal processing. The thermal processing apparatus 100 further includes one or more optical or electrical temperature sensing elements, such as a resistance temperature device (RTD) or thermal couple (T/C), for monitoring the temperature within the process chamber 102 and/or controlling operation of the heating elements 112. In the embodiment shown the temperature sensing element is a profile T/C 114 that has multiple independent temperature sensing nodes or points (not shown) for detecting the temperature at multiple locations within the process chamber 102. The thermal processing apparatus 100 can also include one or more injectors 116 (only one of which is shown) for introducing a fluid, such as a gas or vapor, into the process chamber 102 for processing and/or cooling the wafers 108, and one or more purge ports or vents 118 (only one of which is shown) for introducing a gas to purge the process chamber and/or to cool the wafers. A liner 120 increases the concentration of processing gas or vapor near the wafers 108 in a region or process zone 128 in which the wafers are processed, and reduces contamination of the wafers from flaking or peeling of deposits that can form on interior surfaces of the process chamber 102. Processing gas or vapor exits the process zone through exhaust ports or slots 121 in the chamber liner 120.

Some other suitable configurations for injectors 116, fabrication techniques and materials are described in greater detail in a commonly assigned, co-pending PCT Patent Application Serial No. TBD entitled “Apparatus And Method For Backfilling A Semiconductor Wafer Process Chamber”, which was filed on even date herewith under Attorney Docket No. FP-71750-PC, and which hereby is incorporated herein by reference thereto in its entirely.

Generally, the vessel 101 is sealed by a seal, such as an o-ring 122, to a platform or base-plate 124 to form the process chamber 102, which completely encloses the wafers 108 during thermal processing. The dimensions of the process chamber 102 and the base-plate 124 are selected to provide a rapid evacuation, rapid heating and a rapid backfilling of the process chamber. Advantageously, the vessel 101 and the base-plate 124 are sized to provide a process chamber 102 having dimensions selected to enclose a volume substantially no larger than necessary to accommodate the carrier 106 with the wafers 108 held therein. Preferably, the vessel 101 and the base-plate 124 are sized to provide a process chamber 102 having dimensions of from about 125 to about 150% of that necessary to accommodate the carrier 106 with the wafers 108 held therein, and more preferably, the process chamber has dimensions no larger than about 125% of that necessary to accommodate the carrier and the wafers in order to minimize the chamber volume which aids in pump down and back-fill time required.

Openings for the injectors 116, T/Cs 114 and vents 118 are sealed using seals such as o-rings, VCR®, or CF® fittings. Gases or vapor released or introduced during processing are evacuated through a foreline or exhaust port 126 formed in a wall of the process chamber 102 (not shown) or in a plenum 127 of the base-plate 124, as shown in FIG. 1. The process chamber 102 can be maintained at atmospheric pressure during thermal processing or evacuated to a vacuum as low as 5 millitorr through a pumping system (not shown) including one or more roughing pumps, blowers, hi-vacuum pumps, and roughing, throttle and foreline valves.

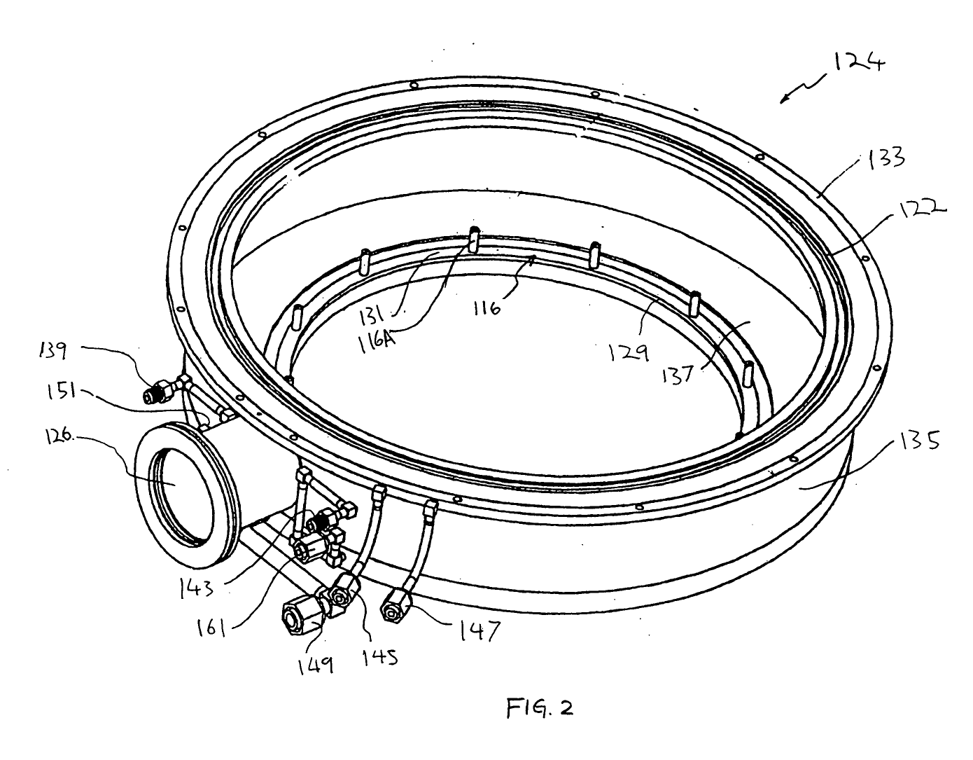

In another embodiment, shown in FIG. 2, the base-plate 124 further includes a substantially annular flow channel 129 adapted to receive and support an injector 116 including a ring 131 from which depend a number of vertical injector tube or injectors 116A. The injectors 116A can be sized and shaped to provide an up-flow, down flow or cross-flow flow pattern, as described below. The ring 131 and injectors 116A are located so as to inject the gas into the process chamber 102 between the boat 106 and the vessel 101. In addition, the injectors 116A are spaced apart around the ring 131 to uniformly introduce process gas or vapor into the process chamber 102, and may, if desired, be used during purging or backfilling to introduce a purge gas into the process chamber. The base-plate 124 is sized in a short cylindrical form with an outwardly extending upper flange 133, a sidewall 135, and an inwardly extending base 137. The upper flange 133 is adapted to receive and support the vessel 101, and contains an o-ring 122 to seal the vessel to the upper flange. The base 137 is adapted to receive and support the liner 120 outside of where the ring 131 of injectors 116 is supported.

Additionally, the base-plate 124 shown in FIG. 2 incorporates various ports including backfill/purge gas inlet ports 139, 143, cooling ports 145, 147, provided to circulate cooling fluid in the base-plate 124, and a pressure monitoring port 149 for monitoring pressure within the process chamber 102. Process gas inlet ports 151, 161, introduce a gas from a supply (not shown) to the injectors 116. The backfill/purge ports 139, 143, are provided at the sidewall 135 of the base-plate 124 principally to introduce a gas from a vent/purge gas supply (not shown) to the vents 118. A mass flow controller (not shown) or any other suitable flow controller is placed in line between the gas supplies and the ports 139, 143, 151 and 161 to control the gas flow into the process chamber 102.

The vessel 101 and liner 120 can be made of any metal, ceramic, crystalline or glass material that is capable of withstanding the thermal and mechanical stresses of high temperature and high vacuum operation, and which is resistant to erosion from gases and vapors used or released during processing. Preferably, the vessel 101 and liner 120 are made from an opaque, translucent or transparent quartz glass having a sufficient thickness to withstand the mechanical stresses and that resists deposition of process byproducts, thereby reducing potential contamination of the processing environment. More preferably, the vessel 101 and liner 120 are made from quartz that reduces or eliminates the conduction of heat away from the region or process zone 128 in which the wafers 108 are processed.

The batch of wafers 108 is introduced into the thermal processing apparatus 100 through a load lock or loadport (not shown) and then into the process chamber 102 through an access or opening in the process chamber or base-plate 124 capable of forming a gas tight seal therewith. In the configuration shown in FIG. 1, the process chamber 102 is a vertical reactor and the access utilizes a movable pedestal 130 that is raised during processing to seal with a seal, such as an o-ring 132 on the base-plate 124, and lowered to enable an operator or an automated handling system, such as a boat handling unit (BHU) (not shown), to position the carrier or boat 106 on the support 104 affixed to the pedestal.

The heating elements 112 include elements positioned proximal to a top 134 (elements 112-3), side 136 (elements 112-2) and bottom 138 (elements 112-1) of the process chamber 102. Advantageously, the heating elements 112 surround the wafers to achieve a good view factor of the wafers and thereby provide an isothermal control volume or process zone 128 in the process chamber in which the wafers 108 are processed. The heating elements 112-1 proximal to the bottom 138 of the process chamber 102 can be disposed in or on the pedestal 130. If desired, additional heating elements may be disposed in or on the base plate 124 to supplement heat from the heating elements 112-1.

In the embodiment shown in FIG. 1 the heating elements 112-1 proximal to the bottom of the process chamber preferably are recessed in the movable pedestal 130. The pedestal 130 is made from a thermally and electrically insulating material or insulating block 140 having an electric, resistive heating elements 112-1 embedded therein or affixed thereto. The pedestal 130 further includes one or more feedback sensors or T/Cs 141 used to control the heating elements 112-1. In the configuration shown, the T/Cs 141 are embedded in the center of the insulating block 140.

The side heating elements 112-2 and the top heating elements 112-3 may be disposed in or on an insulating block 110 about the vessel 101. Preferably the side heating elements 112-2 and the top heating elements 112-3 are recessed in the insulating block 110.

The heating elements 112 and the insulating blocks 110 and 140 may be configured in any of a variety of ways and may be made in any of a variety of ways and with any of a variety of materials. Some suitable configurations, fabrication techniques and materials are well known in the art, and others are described in a PCT Patent Application Serial No. TBD entitled “Variable Heater Element For Low To High Temperature Ranges,” which was filed on even date herewith under Attorney Docket No. FP-71795-PC, and which hereby is incorporated herein by reference thereto in its entirely.

Preferably, to attain desired processing temperatures of up to 1150° C. the heating elements 112-1 proximal to the bottom 138 of the process chamber 102 have a maximum power output of from about 0.1 kW to about 10 kW with a maximum process temperature of at least 1150° C. More preferably, these bottom heating elements 112-1 have a power output of at least about 3.8 kW with a maximum process temperature of at least 950° C. In one embodiment, the side heating elements 112-2 are functionally divided into multiple zones, including a lower zone nearest the pedestal 130 and upper zone, each of which are capable of being operated independently at different power levels and duty cycles from each other and from the top heating elements 112-3 and bottom heating elements 112-1.

The heating elements 112 are controlled in any suitable manner, either by using a control technique of a type well known in the art, or the control technique described in a PCT Patent Application Serial No. TBD entitled “Feed Forward Temperature Controller”, which was filed on even date herewith under Attorney Docket No. FP-71754-PC, and which hereby is incorporated herein by reference thereto in its entirely.

Contamination from the insulating block 140 and bottom heating elements 112-1 is reduced if not eliminated by housing the heating element and insulation block in an inverted quartz crucible 142, which serves as a barrier between the heating element and insulation block and the process chamber 102. The crucible 142 is also sealed against the loadport and BHU environment to further reduce or eliminate contamination of the processing environment. Generally, the interior of the crucible 142 is at standard atmospheric pressure, so that the crucible 142 should be strong enough to withstand a pressure differential between the process chamber 102 and the pedestal 130 across the crucible 142 of as much as 1 atmosphere.

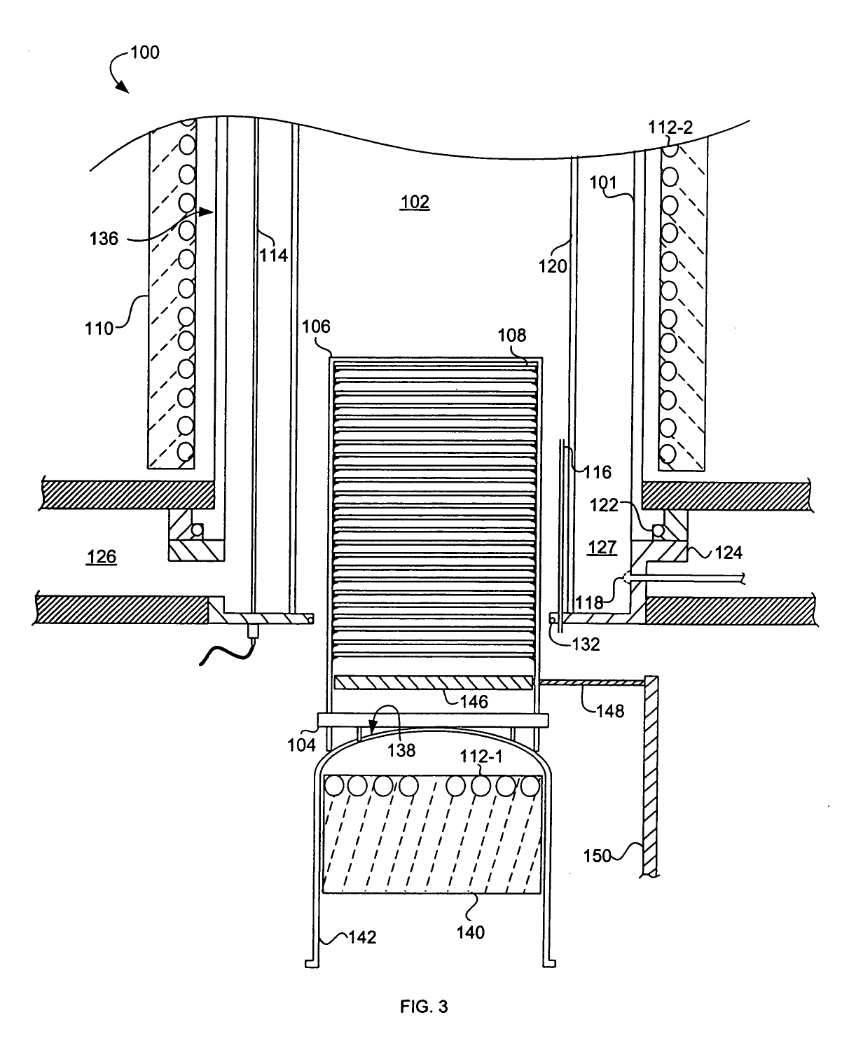

While the wafers 108 are being loaded or unloaded, that is while the pedestal 130 is in the lowered position (FIG. 3), the bottom heating elements 112-1 are powered to maintain an idle temperature lower than the desired processing temperature. For example, for a process having a desired processing temperature for the bottom heating elements of 950° C., the idle temperature can be from 50-150°. The idle temperature can be set higher for certain processes, such as those having a higher desired processing temperature and/or higher desired ramp up rate, or to reduce thermal cycling effects on the bottom heating elements 112-1, thereby extending element life.

In order to further reduce preprocessing time, that is the time required to prepare the thermal processing apparatus 100 for processing, the bottom heating elements 112-1 can be ramped to at or below the desired process temperature during the push or load, that is while the pedestal 130 with a boat 106 of wafers 108 positioned thereon is being raised. However, to minimize thermal stresses on the wafers 108 and components of the thermal processing apparatus 100 it is preferred to have the bottom heating elements 112-1 reach the desired process temperature at the same time as the heating elements 112-3 and 112-2 located proximal to respectively the top 134 and side 136 of the process chamber 102. Thus, for some processes, such as those requiring higher desired process temperatures, the temperature of the bottom heating elements 112-1 can begin being ramped up before the pedestal 130 begins being raised, while the last of the wafers 108 in a batch are being loaded.

Similarly, it will be appreciated that after processing and during the pull or unload cycle, that is while the pedestal 128 is being lowered, power to the bottom heating elements 112-1 can be reduce or removed completely to begin ramping down the pedestal 130 to the idle temperature, in preparation for cooling of the wafers 108 and unloading by the BHU.

To assist in cooling the pedestal 130 to a pull temperature prior to the pull or unload cycle, a purge line for air or an inert purge gas, such as nitrogen, is installed through the insulating block 140. Preferably, nitrogen is injected through a passage 144 through the center of the insulating block 140 and allowed to flow out between the top of the insulating block 140 and the interior of the crucible 142 to a perimeter thereof. The hot nitrogen is then exhausted to the environment either through High Efficiency Particulate Air (HEPA) filter (not shown) or to a facility exhaust (not shown). This center injection configuration facilitates the faster cooling of the center of the wafers 108, and therefore is ideal to minimize the center/edge temperature differential of the bottom wafer or wafers, which could otherwise result in damage due to slip-dislocation of the crystal lattice structure.

As noted above, to increase or extend the life of bottom heating element 112-1 the idle temperature can be set higher, closer to the desired processing temperature to reduce the effects of thermal cycling. In addition, it is also desirable to periodically bake out the heating elements 112-1 in an oxygen rich environment to promote the formation of a protective oxide surface coat. For example, where the resistive heating elements are formed from an Aluminum containing alloy, such as Kanthal®, baking out the heating elements 112-1 in an oxygen rich environment promotes an alumna oxide surface growth. Thus, the insulating block 140 can further include an oxygen line (not shown) to promote the formation of the protective oxide surface coat during bake out of the heating elements 112-1. Alternatively, oxygen for bake out can be introduced through the purge line used during processing to supply cooling nitrogen via a three-way valve.

FIG. 3 is a cross-sectional view of a portion of a thermal processing apparatus 100. FIG. 3 shows the thermal processing apparatus 100 while the wafers 108 are being loaded or unloaded, that is while the pedestal 130 is in the lowered position. In this mode of operation, the thermal processing apparatus 100 further includes a thermal shield 146 that can be rotated or slid into place above the pedestal 130 and the lower wafer 108 in the boat 106. To improve the performance of the thermal shield 146, generally the thermal shield is reflective on the side facing the heating elements 112-1 and absorptive on the side facing the wafers 108. Purposes of the thermal shield 146 include increasing the rate of cooling of the wafers 108 lower down in the boat 106, and assisting in maintaining the idle temperature of the pedestal 130 and bottom heating elements 112-1 to decrease the time required to ramp up the process chamber 102 to the desired processing temperature. An embodiment of a thermal processing apparatus having a thermal shield will now be described in further detail with reference to FIGS. 3 through 6.

FIG. 3 also shows an embodiment of a thermal processing apparatus 100 having pedestal heating elements 112-1 and a thermal shield 146. In the embodiment shown, the thermal shield 146 is attached via arm 148 to a rotable shaft 150 that is turned by an electric, pneumatic or hydraulic actuator to rotate the thermal shield 146 into a first position between the heated pedestal 130 and the lowest of the wafers 108 in the boat 106 during the pull or unload cycle, and removed or rotated to a second position not between the pedestal and the wafers during at least a final portion or end of the push or load cycle, just before the bottom of the boat 106 enters into the chamber 102. Preferably, the rotable shaft 150 is mounted on or affixed to the mechanism (not shown) used for raising and lowering the pedestal 130, thereby enabling the thermal shield 146 to be rotated into position as soon as the top of the pedestal has cleared the process chamber 102. Having the shield 146 in place during the load cycle enables the heating elements 112-1 to be heated to a desired temperature more rapidly than would otherwise be possible. Similarly, during unload cycle the shield 146 helps in cooling the wafers, particularly those closer to the pedestal, by reflect the heat radiating from the pedestal heating elements 112-1.

Alternatively, the rotable shaft 150 can be a mounted on or affixed to another part of the thermal processing apparatus 100 and adapted to move axially in synchronization with the pedestal 130, or to rotate the thermal shield 146 into position only when the pedestal is fully lowered.

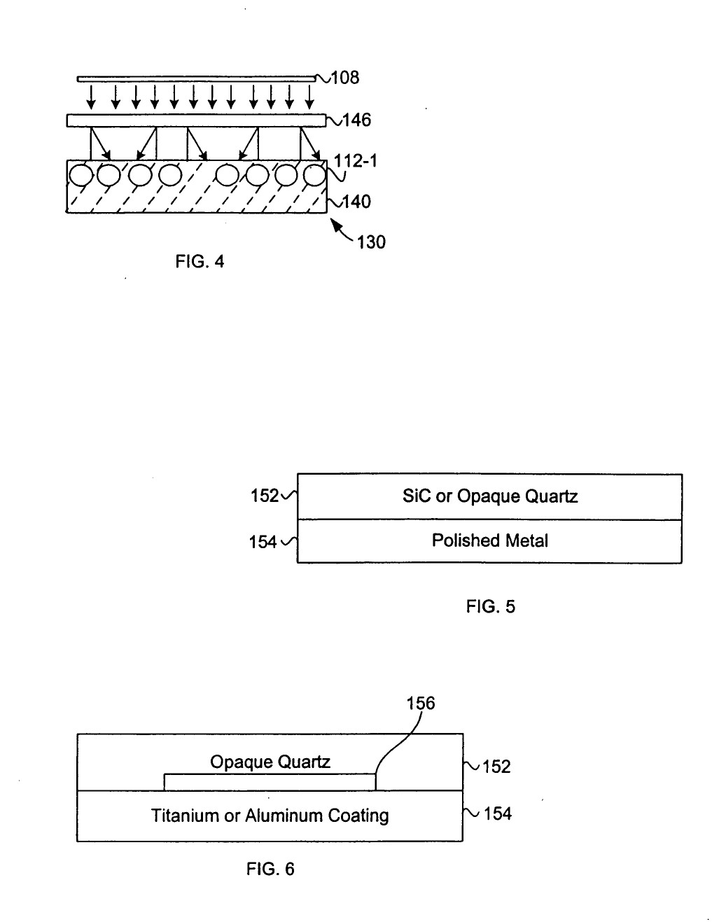

FIG. 4 is a diagrammatic illustration of the pedestal heating elements 112-1 and thermal shield 146 of FIG. 3 illustrating the reflection of thermal energy or heat radiating from the bottom heating elements back to the pedestal 130 and the absorption of thermal energy or heat radiating from the lower wafer 108 in the batch or stack of wafers. It has been determined that the desired characteristics, high reflectivity and high absorptivity, can be obtained using a number of different materials, such as metals, ceramic, glass or polymeric coatings, either individually or in combination. By way of example the following table list various suitable materials and corresponding parameters.

TABLE I

| Material | Absorptivity | Reflectivity |
|---|---|---|
| Stainless Steel | 0.2 | 0.8 |
| Opaque Quartz | 0.5 | 0.5 |
| Polished Aluminum | 0.03 | 0.97 |
| Silicon Carbide | 0.9 | 0.1 |

According to one embodiment the thermal shield 146 can be made from a single material such as silicon-carbide (SiC), opaque quartz or stainless steel which has been polished on one side and scuffed, abraded or roughened on the other. Roughening a surface of the thermal shield 146 can significantly change its heat transfer properties, particularly its reflectivity.

In another embodiment, the thermal shield 146 can be made from two different layers of material. FIG. 5 is a diagrammatic illustration of a thermal shield 146 having a top layer 152 of material such as SiC or opaque quartz, with a high absorptivity and a lower layer 154 of material or metal, such as polished stainless steel or polished aluminum, with a high reflectivity. Although shown as having approximately equal thicknesses, it will be appreciated that either the top layer 152 or the lower layer 154 can have a relatively greater thickness depending on specific requirements for the thermal shield 146, such as minimizing thermal stresses between the layers due to differences in coefficients of thermal expansion. For example, in certain embodiments the lower layer 154 can be an extremely thin layer or film of polished metal deposited, formed or plated on a quartz plate that forms the top layer 152. The materials can be integrally formed or interlocking, or joined by conventional means such as bonding or fasteners.

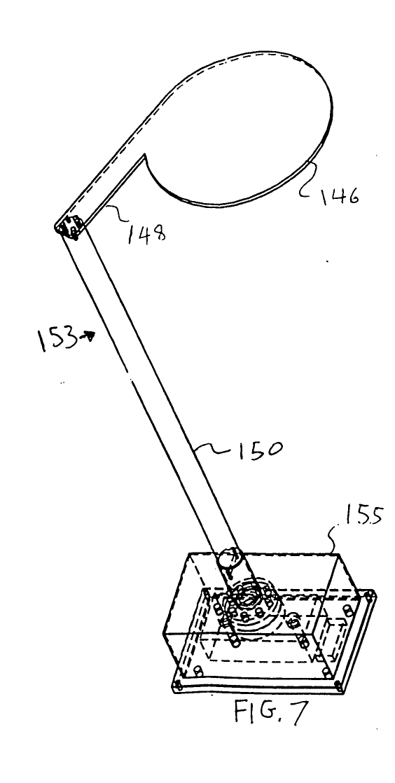

In yet another embodiment, the thermal shield 146 further includes an internal cooling channel 156 to further insulate the wafers 108 from the bottom heating elements 112-1. In one version of this embodiment, shown in FIG. 6, the cooling channel 156 is formed between two different layers 152 and 154 of material. For example, the cooling channel 156 can be formed by milling or any other suitable technique in a highly absorptive opaque quartz layer 152, and be covered by a metal layer 154 or coating such as a Titanium or Aluminum coating. Alternatively, the cooling channel 156 can be formed in the metal layer 154 or both the metal layer and the quartz layer 152.

FIG. 7 is a perspective view of an embodiment of a thermal shield assembly 153 including the thermal shield 146, arm 148, rotable shaft 150 and an actuator 155.

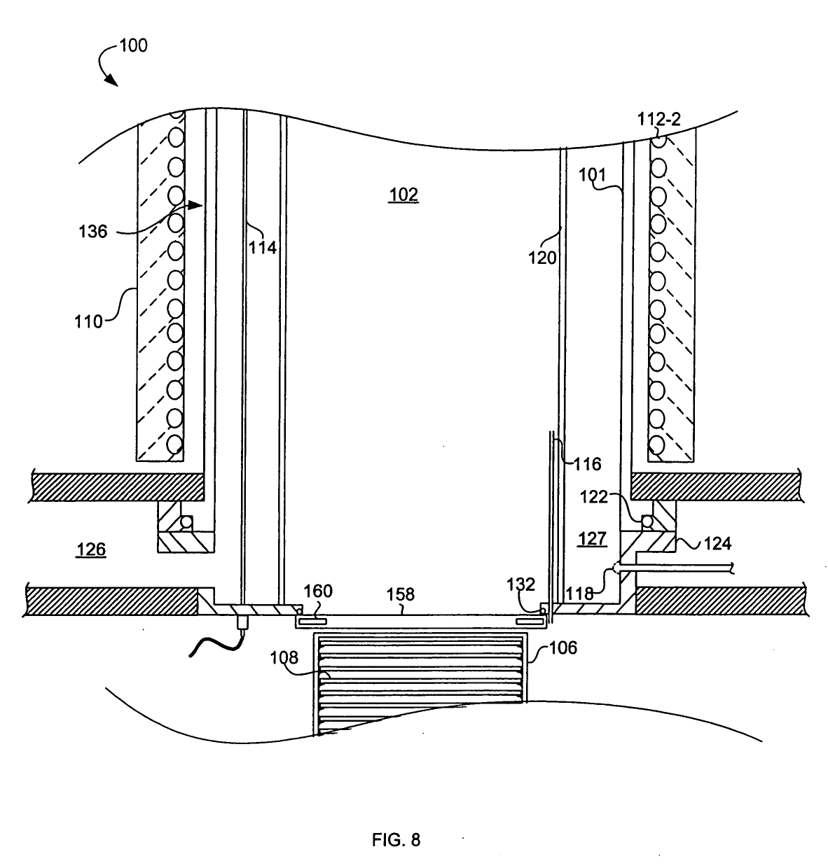

As shown in FIG. 8, the thermal processing apparatus 100 further includes a shutter 158 that can be rotated or slid or otherwise moved into place above the boat 106 to isolate the process chamber 102 from the outside or load port environment when the pedestal 130 is in the fully lowered position. For example, the shutter 158 can be slid into place above the carrier 106 when the pedestal 130 is in a lowered position, and raised to isolate the process chamber 102. Alternatively, the shutter 158 can be rotated or swung into place above the carrier 106 when the pedestal 130 is in a lowered position, and subsequently raised to isolate the process chamber 102. Optionally, the shutter 158 may be rotated about or relative to threaded screw or rod to simultaneously raise the shutter to isolate the process chamber 102 as it is swung into place above the carrier 106.

For a process chamber 102 that is normally operated under vacuum, such as in a CVD system, the shutter 158 could form a vacuum seal against the base-plate 124 to allow the process chamber 102 to be pumped down to the process pressure or vacuum. For example, it may be desirable to pump down the process chamber 102 between sequential batches of wafers to reduce or eliminate the potential for contaminating the process environment. Forming a vacuum seal is preferably done with a large diameter seal, such as an o-ring, and thus the shutter 158 can desirably include a number of water channels 160 to cool the seal. In the embodiment shown in FIG. 8 the shutter 158 seals with the same o-ring 132 used to seal with the crucible 142 when the pedestal 130 is in the raised position.

For a thermal processing apparatus 130 in which the process chamber 102 is normally operated at atmospheric pressure, the shutter 158 is simply an insulating plug designed to reduce heat loss from the bottom of the process chamber. One embodiment for accomplishing this involves the use of an opaque quartz plate, which may or may not further include a number of cooling channels underneath or internal thereto.

When the pedestal 130 is in the fully lowered position, the shutter 158 is moved into position below the process chamber 102 and then raised to isolate the process chamber by one or more electric, hydraulic or pneumatic actuators (not shown). Preferably, the actuators are pneumatic actuators using from about 15 to 60 pounds per square inch gauge (PSIG) air, which is commonly available on thermal processing apparatus 100 for operation of pneumatic valves. For example, in one version of this embodiment the shutter 158 can comprise a plate having a number of wheels attached via short arms or cantilevers to two sides thereof. In operation, the plate or shutter 158 is rolled into position beneath the process chamber 102 on two parallel guide rails. Stops on the guide rails then cause the cantilevers to pivot translating the motion of the shutter 158 into an upward direction to seal the process chamber 102.

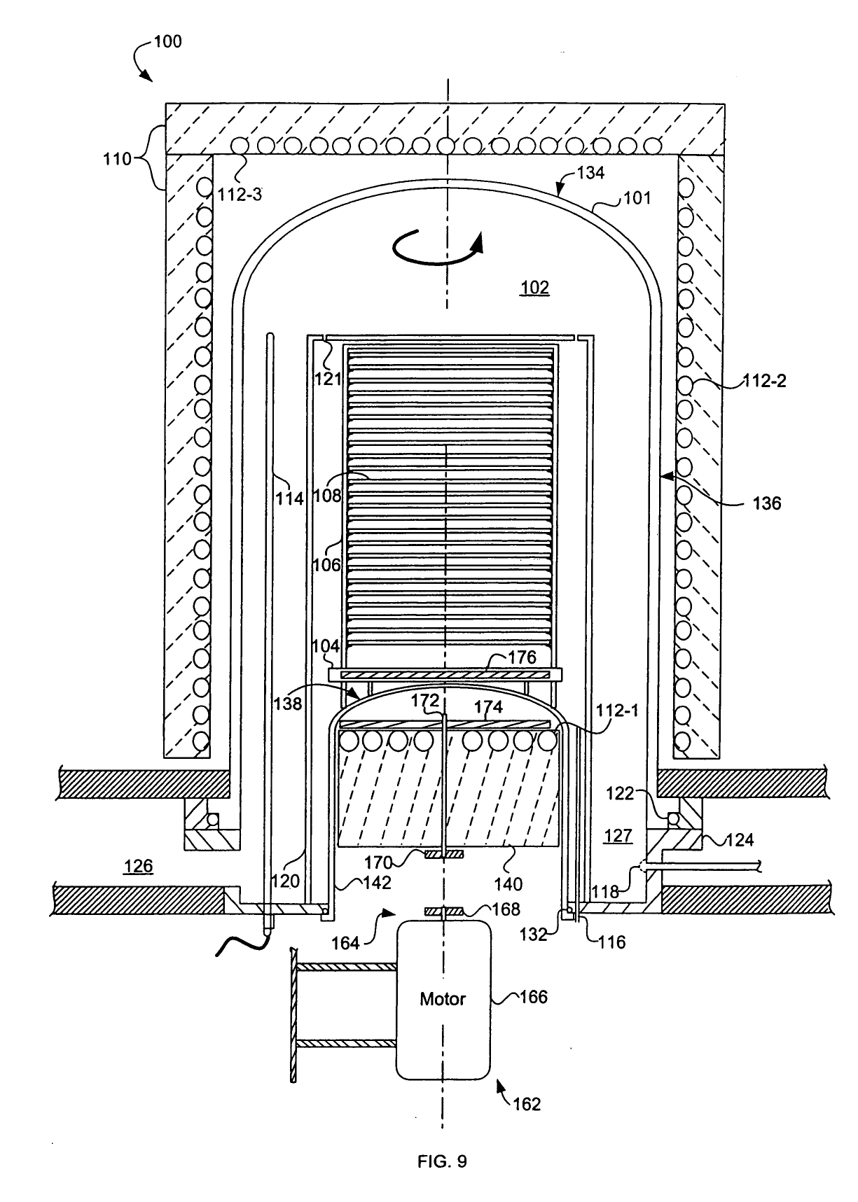

As shown in FIG. 9, the thermal processing apparatus 100 further includes a magnetically coupled wafer rotation system 162 that rotates the support 104 and the boat 106 along with the wafers 108 supported thereon during processing. Rotating the wafers 108 during processing improves within wafer (WIW) uniformity by averaging out any non-uniformities in the heating elements 112 and in process gas flows to create a uniform on-wafer temperature and species reaction profile. Generally, the wafer rotation system 162 is capable of rotated the wafers 108 at a speed of from about 0.1 to about 10 revolutions per minute (RPM).

The wafer rotation system 162 includes a drive assembly or rotating mechanism 164 having a rotating motor 166, such as an electric or pneumatic motor, and a magnet 168 encased in a chemically resistive container, such as annealed polytetrafluoroethylene or stainless steel. A steel ring 170 located just below the insulating block 140 of the pedestal 130, and a drive shaft 172 with the insulating block transfer the rotational energy to another magnet 174 located above the insulating block in a top portion of the pedestal. The steel ring 170, drive shaft 172 and second magnet 174 are also encased in a chemically resistive container compound. The magnet 174 located in the side of the pedestal 130 magnetically couples through the crucible 142 with a steel ring or magnet 176 embedded in or affixed to the support 104 in the process chamber 102.

Magnetically coupling the rotating mechanism 164 through the pedestal 130 eliminates the need for locating it within the processing environment or for having a mechanical feedthrough, thereby eliminating a potential source of leaks and contamination. Furthermore, locating rotating mechanism 164 outside and at some distance from the processing minimizes the maximum temperature of to which it is exposed, thereby increasing the reliability and operating life of the wafer rotation system 162.

In addition to the above, the wafer rotation system 162 can further include one or more sensors (not shown) to ensure proper boat 106 position and proper magnetic coupling between the steel ring or magnet 176 in the process chamber 102 and the magnet 174 in the pedestal 130. A sensor which determines the relative position of the boat 106, or boat position verification sensor, is particularly useful. In one embodiment, the boat position verification sensor includes a sensor protrusion (not shown) on the boat 106 and an optical or laser sensor located below the base-plate 124. In operation, after the wafers 108 have been processed and the pedestal 130 is lowered about 3 inches below the base-plate 124. There, the wafer rotation system 162 is commanded to turn the boat 106 until the boat sensor protrusion can be seen. Then, the wafer rotation system 162 is operated to align the boat so that the wafers 108 can be unloaded. After this is done, the boat is lowered to the load/unload height. After the initial check, it is only capable of verifying the boat location from the flag sensor.

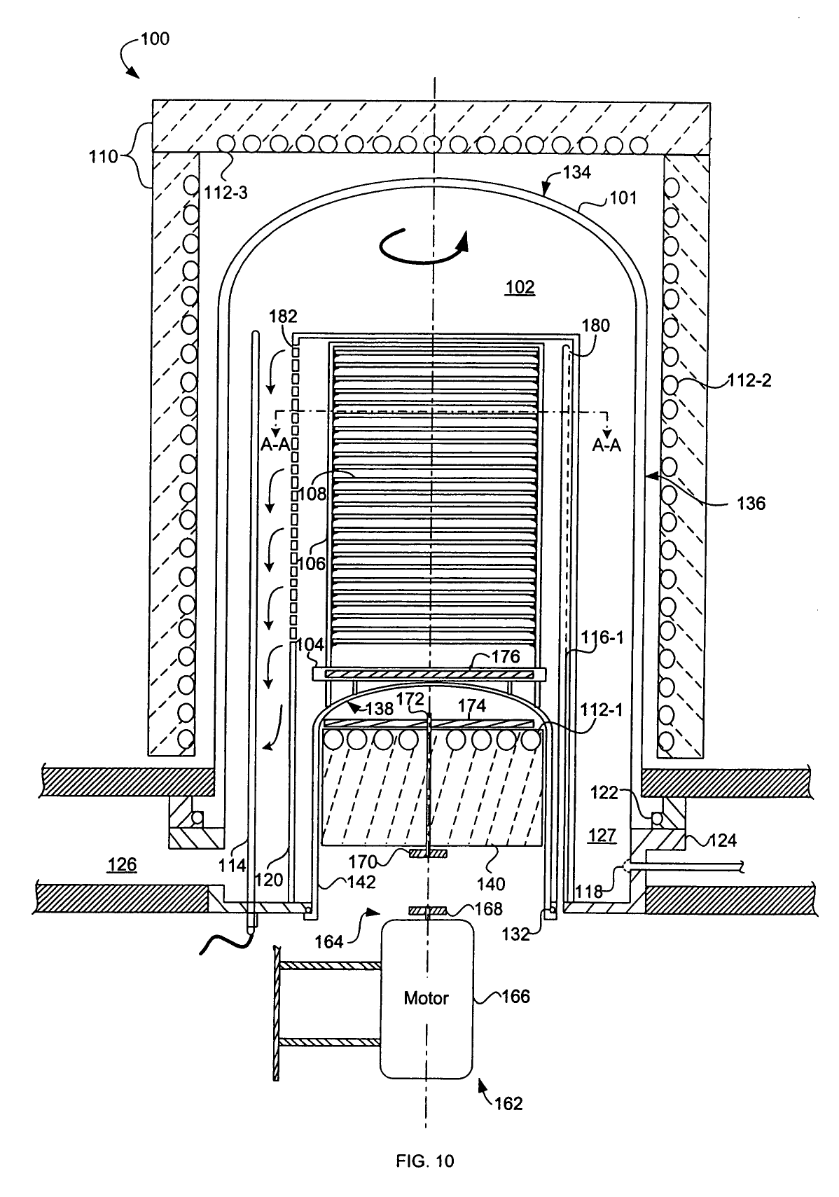

As shown in FIG. 10, improved injectors 216 are preferably used in the thermal processing apparatus 100. The injectors 216 are distributive or cross(X)-flow injectors 216-1 in which process gas or vapor is introduced through injector openings or orifices 180 on one side of the wafers 108 and boat 106 and caused to flow across the surfaces of the wafers in a laminar flow to exit exhaust ports or slots 182 in the chamber line 120 on opposite the side. X-flow injectors 116-1 improve wafer 108 to wafer uniformity within a batch of wafers 108 by providing an improved distribution of process gas or vapor over earlier up-flow or down flow configurations.

Additionally, X-flow injectors 216 can serve other purposes, including the injection of gases for cool-down (e.g., helium, nitrogen, hydrogen) for forced convective cooling between the wafers 108. Use of X-flow injectors 216 results in a more uniform cooling between wafers 108 whether disposed at the bottom or top of the stack or batch and those wafers that are disposed in the middle, as compared with earlier up-flow or down flow configurations. Preferably, the injector 216 orifices 180 are sized, shaped and position to provide a spray pattern that promotes forced convective cooling between the wafers 108 in a manner that does not create a large temperature gradient across the wafer.

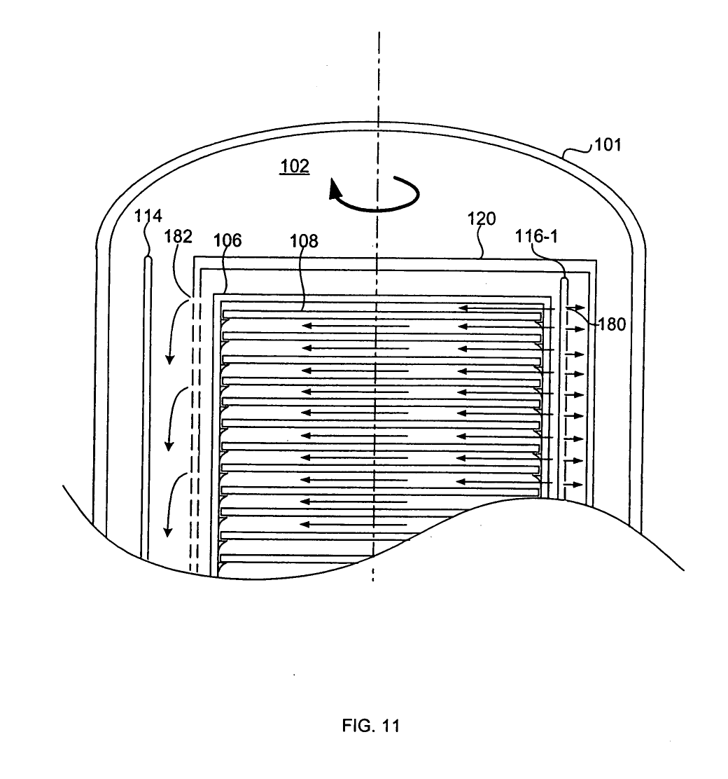

FIG. 11 is a cross-sectional side view of a portion of the thermal processing apparatus 100 of FIG. 10 showing illustrative portions of the injector orifices 180 in relation to the chamber liner 120 and the exhaust slots 182 in relation to the wafers 108.

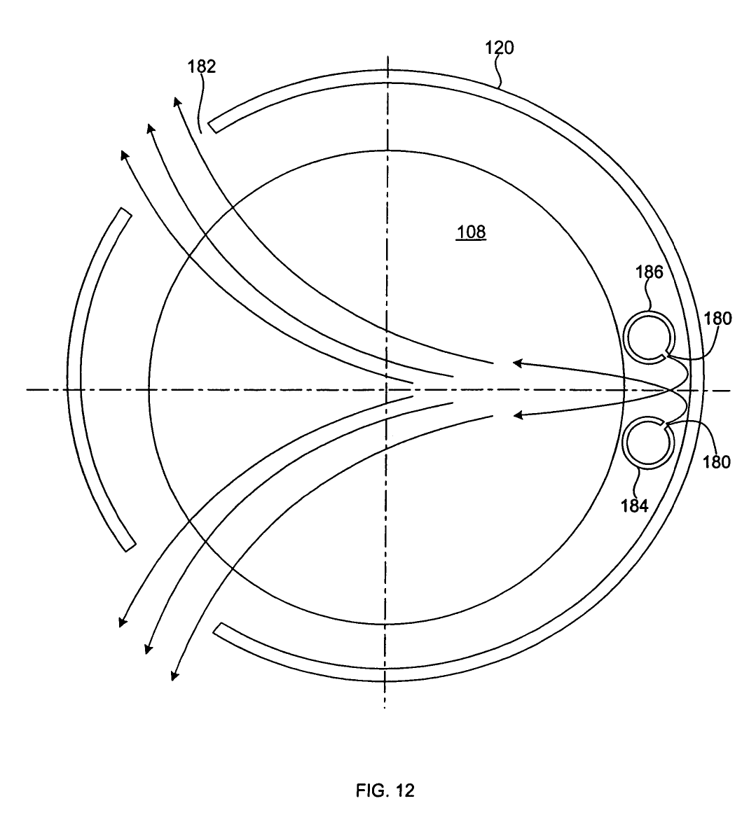

FIG. 12 is a plan view of a portion of the thermal processing apparatus 100 of FIG. 10 taken along the line A-A of FIG. 10 showing laminar gas flow from the orifices 180-1 and 180-2 of primary and secondary injectors 184, 186, across an illustrative one of the wafers 108 and to exhaust slots 182-1 and 182-2 according to one embodiment. It should be noted that the position of the exhaust slot 182 as shown in FIG. 10 have been shifted from the position of exhaust slots 182-1 and 182-2 shown in FIG. 12 to allow illustration of the exhaust slot and injector 116-1 in a single a cross-sectional view of a thermal processing apparatus. It should also be noted that the dimensions of the injectors 184, 186, and the exhaust slots 182-1 and 182-2 relative to the wafer 108 and the chamber liner 120 have been exaggerated to more clearly illustrate the gas flow from the injectors to the exhaust slots.

Also as shown in FIG. 12, the process gas or vapor is initially directed away from the wafers 108 and toward the liner 120 to promote mixing of the process gas or vapor before it reaches the wafers. This configuration of orifices 180-1 and 180-2 is particularly useful for processes or recipes in which different reactants are introduced from each of the primary and secondary injectors 184, 186, for example to form a multi-component film or layer.

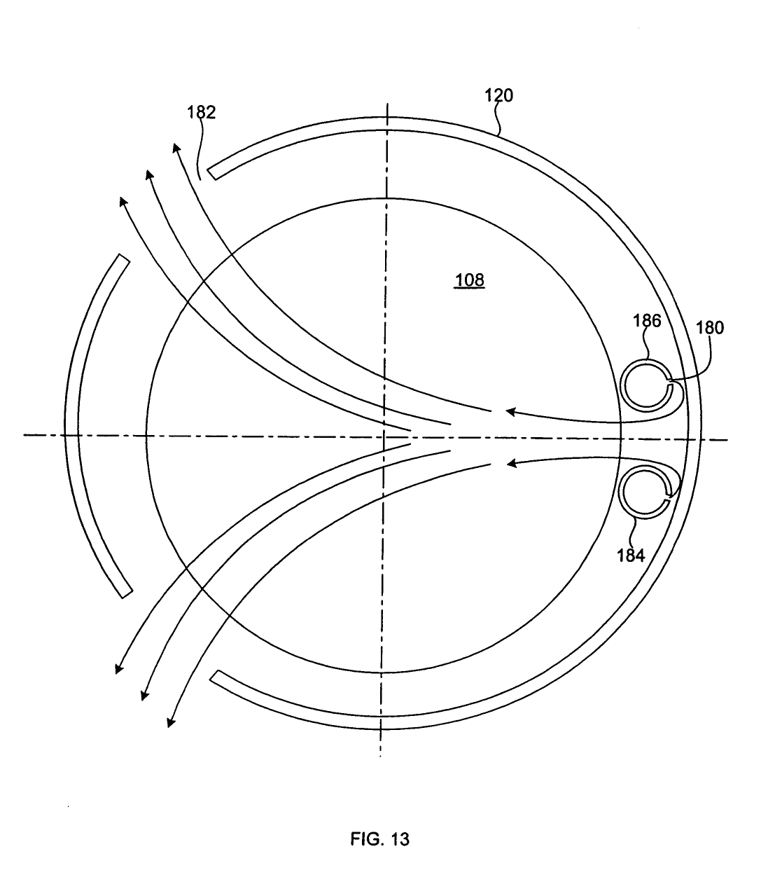

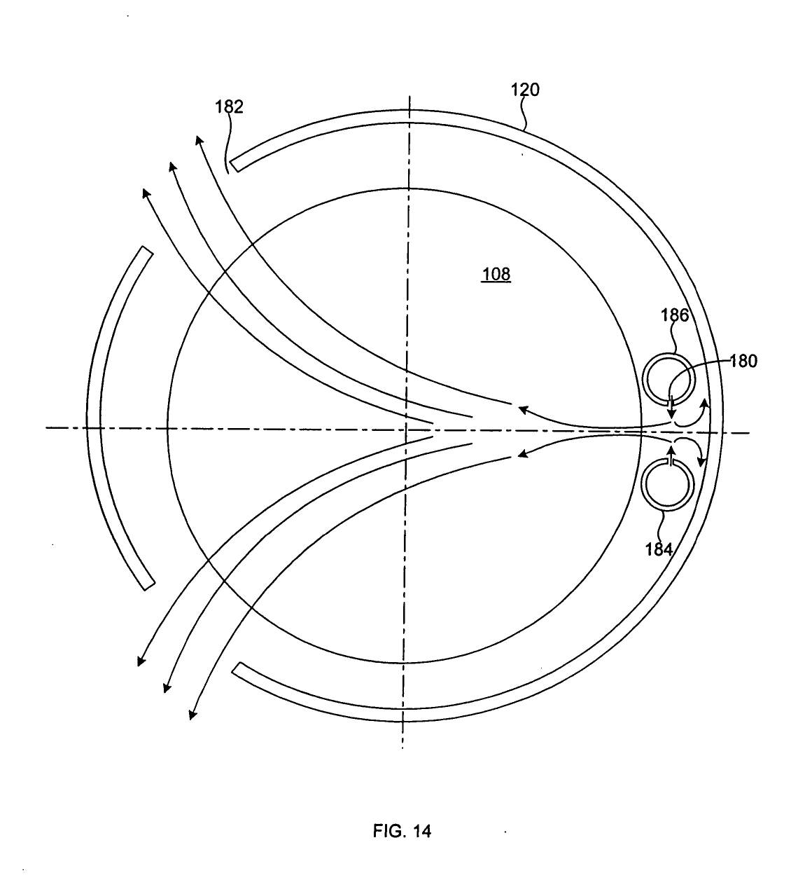

FIG. 13 is another plan view of a portion of the thermal processing apparatus 100 of FIG. 10 taken along the line A-A of FIG. 10 showing an alternative gas flow path from the orifices 180 of the primary and secondary injector 184, 186, across an illustrative on of the wafer 108 and to the exhaust slots 182 according to another embodiment.

FIG. 14 is another plan view of a portion of the thermal processing apparatus 100 of FIG. 10 taken along the line A-A of FIG. 10 showing an alternative gas flow path from the orifices 180 of the primary and secondary injector 184, 186, across an illustrative on of the wafer 108 and to the exhaust slots 182 according to yet another embodiment.

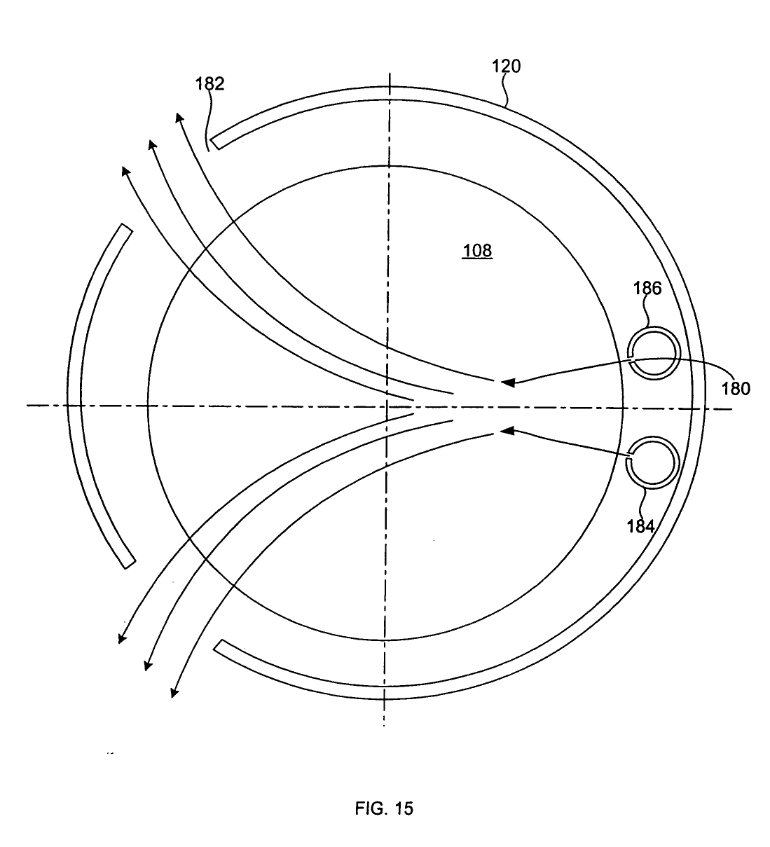

FIG. 15 is another plan view of a portion of the thermal processing apparatus 100 of FIG. 10 taken along the line A-A of FIG. 10 showing an alternative gas flow path from the orifices 180 of the primary and secondary injector 184, 186, across an illustrative on of the wafer 108 and to the exhaust slots 182 according to still another embodiment.

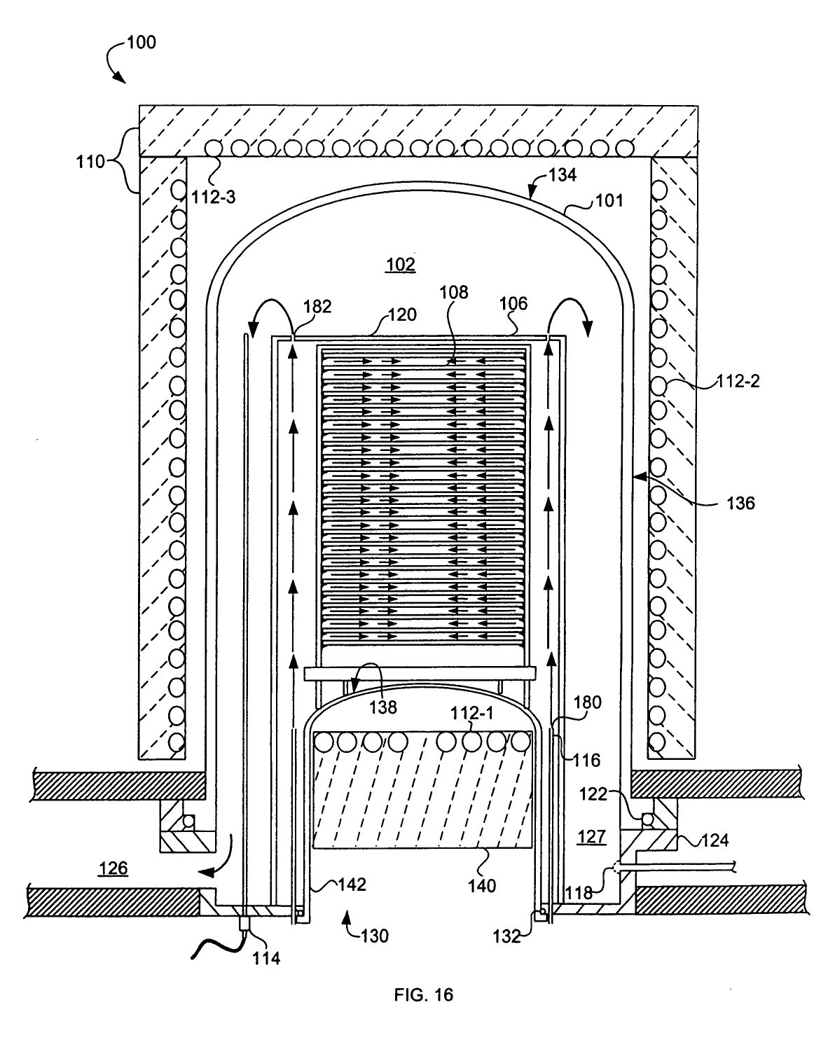

FIG. 16 is a cross-sectional view of a thermal processing apparatus 100 having two or more up-flow injectors 116-1 and 116-2 according to an alternative embodiment. In this embodiment, process gas or vapor admitted from the process injectors 116-1 and 116-2 having respective outlet orifices low in the process chamber 102 flows up and across the wafers 108, and spent gases exit exhaust slots 182 in the top of the liner 120. An up-flow injector system is also shown in FIG. 1.

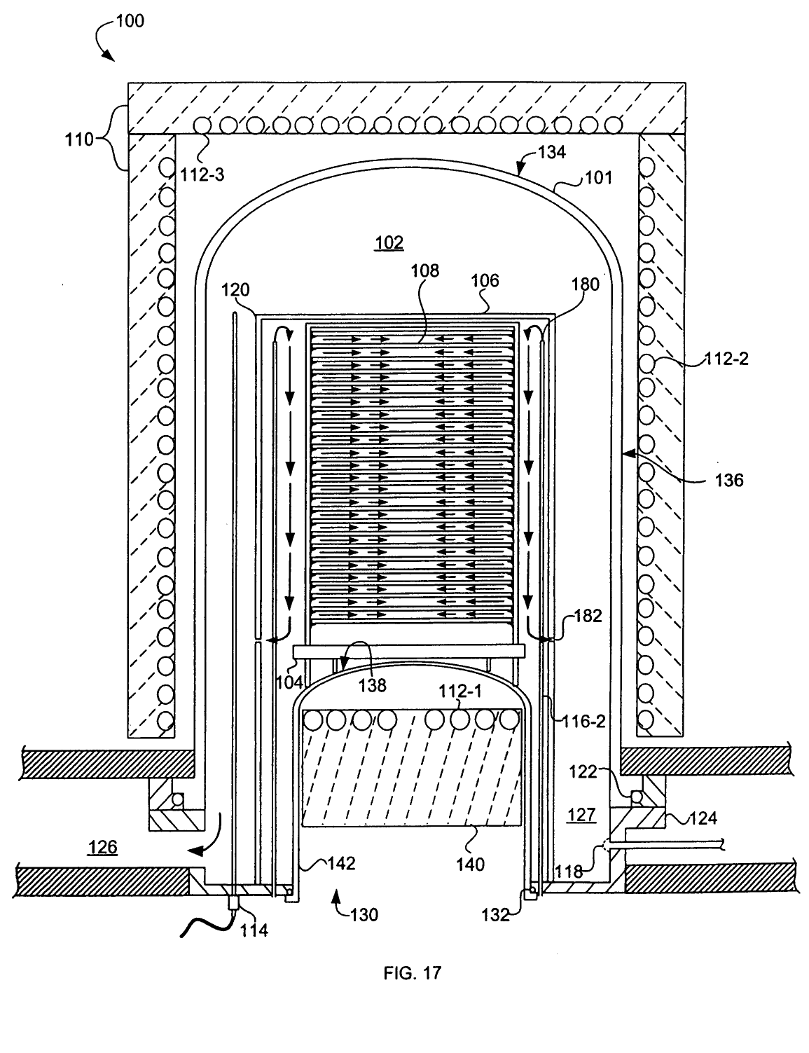

FIG. 17 is a cross-sectional view of a thermal processing apparatus 100 having a down-flow injector system according to an alternative embodiment. In this embodiment, process gas or vapor admitted from process injectors 116-1 and 116-2 having respective orifices high in the process chamber 102 flows down and across the wafers 108, and spent gases exit exhaust slots 182 in the lower portion of the liner 120.

Advantageously, the injectors 116, 216, and/or the liner 120 can be quickly and easily replaced or swapped with other injectors and liners having different points for the injection and exhausting of the process gas from the process zone 128. It will be appreciated by those skilled in the art that the embodiment of the x-flow injector 216 shown in FIG. 10 adds a degree of process flexibility by enabling the flow pattern within the process chamber 102 to be quickly and easily changed from a cross-flow configuration, as shown in FIG. 10, to an up-flow configuration, as shown in FIGS. 1 and 16, or a down-flow configuration, as shown in FIG. 17. This can be accomplished through the use of easily installable injector assemblies 216 and liners 120 to convert the flow geometry from cross-flow to an up-flow or down-flow.

The injectors 116, 216, and the liner 120 can be separate components, or the injector can be, integrally formed with liner as a single piece. The latter embodiment is particular useful in applications where it is desirable to frequently change the process chamber 102 configuration.

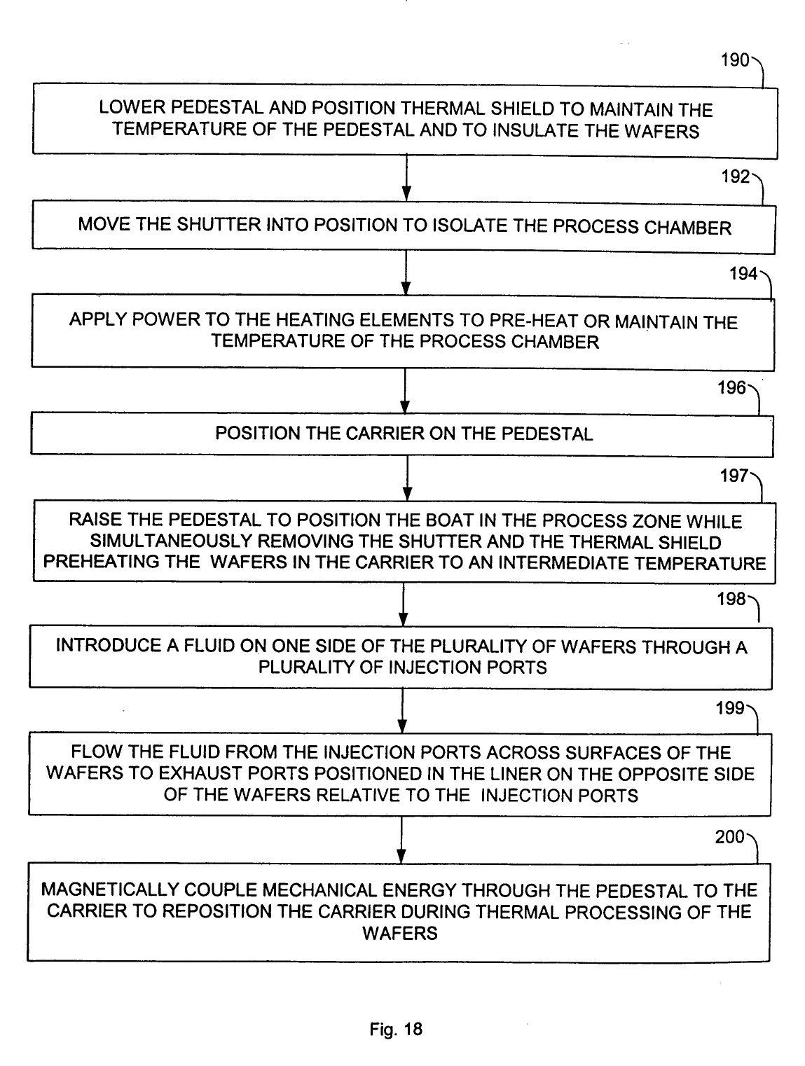

An illustrative method or process for operating the thermal processing apparatus 100 is described with reference to FIG. 18. FIG. 18 is a flowchart showing steps of a method for thermally processing a batch of wafers 108 wherein each wafer of the batch of wafers is quickly and uniformly heated to the desired temperature. In the method, the pedestal 130 is lowered, and the thermal shield 142 is moved into a position while the pedestal 130 is lowered to reflect heat from the bottom heating element 112-1 back to the pedestal 130 to maintain the temperature thereof, and to insulate the finished wafers 108 (step 190). Optionally, the shutter 158 is moved into position to seal or isolate the process chamber 102 (step 192), and power is applied to the heating elements 112-2, 112-3, to begin pre-heating the process chamber 102 to or maintain at an intermediate or idling temperature (step 194). A carrier or boat 106 loaded with new wafers 108 is positioned on the pedestal 130 (step 196). The pedestal 130 is raised to position the boat in the process zone 128, while simultaneously removing the shutter 158, the thermal shield 142, and ramping-up the bottom heating element 112-1 to preheat the wafers to an intermediate temperature (step 197). Preferably, the thermal shield 142 is removed just before the boat 106 is positioned in the process zone 128. A fluid, such as a process gas or vapor, is introduced on one side of the of wafers 108 through a plurality of injection ports 180 (step 198). The fluid flows from the injection ports 180 across surfaces of the wafers 108 to exhaust ports 182 positioned in the liner 120 on the opposite side of the wafers relative to the injection ports (step 199). Optionally, the boat 106 can be rotated within the process zone 128 during thermal processing of the batch of wafers 108 to further enhance uniformity of the thermal processing, by magnetically coupling mechanical energy through the pedestal 130 to the carrier or boat 106 to reposition it during thermal processing of the wafers (step 200).

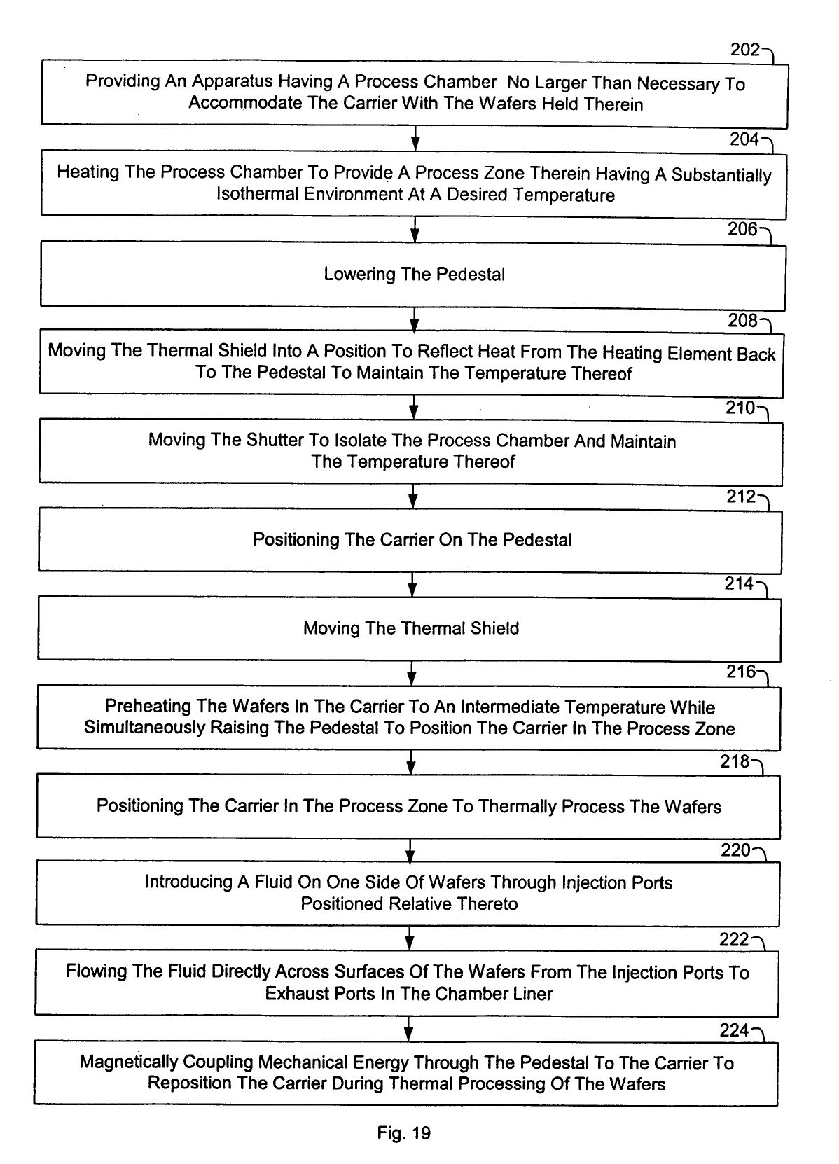

A method or process for a thermal processing apparatus 100 according to another embodiment will now be described with reference to FIG. 19. FIG. 19 is a flowchart showing steps of an embodiment of a method for thermally processing a batch of wafers 108 in a carrier. In the method, an apparatus 100 is provided having a process chamber 102 with dimensions and a volume not substantially larger than necessary (guard heaters absent) to accommodate the carrier 106 with the wafers 108 held therein. The pedestal 130 is lowered, and the boat 106 with the wafers 108 held therein positioned thereon (step 202). The pedestal 130 is raised to insert the boat in the process chamber 102, while simultaneously preheating the wafers 108 to an intermediate temperature (step 204). Power is applied to the heating elements 112-1, 112-2, 112-3, each disposed proximate to at least one of the top wall 134, the side wall 136 and the bottom wall 138 of the process chamber 102 to begin heating the process chamber (step 206). Optionally, power to at least one of the heating elements is adjusted independently to provide a substantially isothermal environment at a desired temperature in a process zone 128 in the process chamber 102 (step 208). When the wafers 108 have been thermally processed, and while maintaining the desired temperature in the process zone 128, the pedestal 130 is lowered, and the thermal shield 142 is moved into position to insulate the finished wafers 108 and to reflect heat from the bottom heating element 112-1 back to the pedestal 130 to maintain the temperature thereof (step 210). Also, optionally, the shutter 158 is moved into position to seal or isolate the process chamber 102, and power applied to the heating elements 112-2, 112-3, to maintain the temperature of the process chamber (step 212). The boat 106 is then removed from the pedestal 130 (step 214), and another boat loaded with a new batch of wafers to be processed positioned on the pedestal (step 216). The shutter 158 is repositioned or removed (step 218), and the thermal shield withdrawn or repositioned to preheat the wafers 108 in the boat 106 to an intermediate temperature while simultaneously raising the pedestal 130 to insert the boat into the process chamber 102 to thermally process the new batch of wafers (step 220).

It has been determined that the thermal processing apparatus 100 provided and operated as described above, reduces the processing or cycle time by about 75% over conventional systems. For example, a conventional large batch thermal processing apparatus may process 100 product wafers in about 232 minutes, including pre-processing and post-processing time. The inventive thermal processing apparatus 100 performs the same processing on a mini-batch of 25 product wafers 108 in about 58 minutes.

The foregoing description of specific embodiments and examples of the invention have been presented for the purpose of illustration and description, and although the invention has been described and illustrated by certain of the preceding examples, it is not to be construed as being limited thereby. They are not intended to be exhaustive or to limit the invention to the precise forms disclosed, and many modifications, improvements and variations within the scope of the invention are possible in light of the above teaching. It is intended that the scope of the invention encompass the generic area as herein disclosed, and by the claims appended hereto and their equivalents.

What is claimed is:

1. An apparatus for thermally processing a plurality of substrates held in a carrier, the apparatus comprising:
a process chamber having a top wall, a side wall and a bottom wall including a pedestal;
a heating source having a plurality of heating elements to thermally process the plurality of substrates, each of the plurality of heating elements proximal to at least one of the top wall, the side wall and the bottom wall of the process chamber, and at least one of the plurality of heating elements in the pedestal; and
a removable thermal shield adapted to be inserted between the at least one of the plurality of heating elements in the pedestal and the substrates held the carrier.

2. An apparatus according to claim 1, wherein the thermal shield comprises a first surface facing the substrates held the carrier, the first surface having an absorptivity of at least 0.5.

3. An apparatus according to claim 2, wherein the thermal shield comprises a second surface facing the pedestal, the second surface having a reflectivity of at least 0.8.

4. An apparatus according to claim 3, wherein the thermal shield further comprises a cooling channel between the first and second surfaces.

5. An apparatus according to claim 1, wherein the thermal shield comprises a reflective surface and a absorptive surface comprising materials selected from the group consisting of:
Stainless Steel
Quartz
Aluminum; and
Silicon Carbide.

6. An apparatus according to claim 1, wherein the thermal shield comprises stainless steel having a polished reflective surface facing the pedestal, and a non-polished absorptive surface facing the substrates on the carrier.

7. An apparatus for thermally processing a plurality of substrates, comprising:
a thermal process chamber;
a pedestal having an open position with respect to the process chamber, a closed position with respect to the process chamber, and a varying position between the open and closed positions;
a distributed heating source for establishing substantially uniform heat throughout a process zone within the process chamber, with the pedestal in the closed position;
a thermal shield; and
a positioner coupled to the thermal shield for removably positioning the thermal shield between the pedestal and the process chamber at least while the pedestal is in the varying position.

8. An apparatus for thermally processing a plurality of substrates held in a carrier, the apparatus comprising:
a process chamber having a top wall, a side wall and a bottom wall;
a heating source having a plurality of heating elements to thermally process the plurality of substrates, each of the plurality of heating elements proximal to at least one of the top wall, the side wall and the bottom wall of the process chamber; and
a magnetically coupled repositioning system that repositions the carrier with the plurality of substrates held therein during thermal processing of the plurality of substrates, wherein the mechanical energy to reposition the carrier is magnetically coupled through the bottom wall to the carrier.

9. An apparatus according to claim 8, wherein the bottom wall includes a movable pedestal having at least one of the plurality of heating elements therein, and wherein the mechanical energy to reposition the carrier is magnetically coupled through the movable pedestal substantially without moving the at least one of the plurality of heating elements in the movable pedestal.

10. An apparatus according to claim 8, wherein the magnetically coupled repositioning system is adapted to rotate the carrier with the plurality of substrates held therein during thermal processing of the plurality of substrates.

11. An apparatus according to claim 10, wherein the magnetically coupled repositioning system is adapted to rotate the carrier at a speed of from about 0.1 to about 10 revolutions per minute (RPM).

12. An apparatus according to claim 8, wherein the magnetically coupled repositioning system is adapted to oscillate the carrier.

13. An apparatus according to claim 8, wherein the carrier comprises a magnetic member to which the mechanical energy to reposition the carrier is magnetically coupled through the bottom wall.

14. An apparatus according to claim 8, further comprising a support on which the carrier is positioned in the process chamber, and wherein the support comprises a magnetic member to which the mechanical energy to reposition the carrier is magnetically coupled through the bottom wall.

15. An apparatus according to claim 8, wherein the mechanical energy to reposition the carrier is magnetically coupled through the bottom wall to the carrier without the use of a movable feedthrough into the process chamber

16. An apparatus for thermally processing a plurality of substrates, comprising:
a process chamber enclosure defining a thermal process chamber within;
a carrier support disposed in the process chamber for supporting a carrier containing a plurality of substrates during thermal processing;
a distributed heating source for establishing substantially uniform heat throughout a process zone within the process chamber during thermal processing; and
a repositioning system magnetically coupled to the carrier support through the process chamber enclosure for repositioning the carrier support during thermal processing, wherein the substrates are repositioned in the process zone.

17. An apparatus for thermally processing a plurality of substrates held in a carrier, the apparatus comprising:
a process chamber having a top wall, a side wall and a bottom wall including a movable pedestal adapted to be lowered and raised to enable the carrier with the plurality of substrates held therein to be inserted into and removed from the process chamber;
a heating source having a plurality of heating elements proximal to the process chamber to thermally process the plurality of substrates, at least one of the plurality of heating elements in the movable pedestal; and
a shutter adapted to be moved into place above the carrier to isolate the process chamber when the pedestal is in a lowered position.

18. An apparatus according to claim 17, further comprising a pumping system to evacuate the process chamber prior to processing, and wherein the shutter is adapted to seal with the process chamber to enable the pumping system to evacuate the process chamber when the pedestal is in the lowered position.

19. An apparatus according to claim 17, wherein the shutter comprises a cooling channel.

20. An apparatus according to claim 17, wherein the shutter is adapted to be swung into place above the carrier when the pedestal is in a lowered position, and raised to isolate the process chamber.

21. An apparatus according to claim 17, wherein the shutter is adapted to be slid into place above the carrier when the pedestal is in a lowered position, and raised to isolate the process chamber.

22. An apparatus for thermally processing a plurality of substrates, comprising:
a process chamber enclosure defining a process chamber within;
a shutter disposed upon the process chamber enclosure;
a pedestal having an open position with respect to the process chamber, a closed position with respect to the process chamber, and a varying position between the open and closed positions, the pedestal being movable through the shutter;
a distributed heating source for establishing substantially uniform heat throughout a process zone within the process chamber with the pedestal in the closed position; and
an actuator coupled to the shutter for opening the shutter while the pedestal is in the closed and varying positions, and for closing the shutter when the pedestal is in the open position.

23. An apparatus for thermally processing a plurality of substrates held in a carrier, the apparatus comprising:
a process chamber having a top wall, a side wall and a bottom wall;
a heating source having a plurality of heating elements to thermally process the plurality of substrates, each of the plurality of heating elements proximal to at least one of the top wall, the side wall and the bottom wall of the process chamber;
a liner separating the carrier with the plurality of substrates held therein from the top wall and the side wall of the process chamber; and
a cross-flow injection system to direct flow of a fluid across surfaces of each of the plurality of substrates, the cross-flow injection system including:
a cross-flow injector having a plurality of injection ports positioned relative to the plurality of substrates held in the carrier, and through which a fluid is introduced on one side of the plurality of substrates; and
a plurality of exhaust ports in the liner, the exhaust ports positioned relative to the plurality of substrates held in the carrier to cause the fluid to flow directly across surfaces of the plurality of substrates.

24. An apparatus according to claim 23, wherein the plurality of injection ports are positioned to direct flow of the fluid against the liner prior to the fluid flowing across the surfaces of each of the plurality of substrates.

25. An apparatus according to claim 23, wherein the cross-flow injector comprises a first injector and a second injector, each having a plurality of injection ports positioned relative to the plurality of substrates held in the carrier.

26. An apparatus according to claim 25, wherein the plurality of injection ports of the first injector and the second injector are positioned to direct flow of the fluid against the liner prior to the fluid flowing across the surfaces of each of the plurality of substrates,
whereby reactants in the fluid introduced by the first injector and the second injector are mixed prior to the fluid flowing across the surfaces of each of the plurality of substrates.

27. An apparatus according to claim 25, wherein the plurality of injection ports of the first injector and the second injector are positioned relative to one another to direct flow of the fluid from the plurality of injection ports of the first injector prior toward the second injector, and to direct flow of the fluid from the plurality of injection ports of the second injector prior toward the first injector,
whereby reactants in the fluid introduced by the first injector and the second injector are mixed prior to the fluid flowing across the surfaces of each of the plurality of substrates.

28. An apparatus for thermally processing a plurality of substrates, comprising:
a process chamber enclosure defining a thermal process chamber within;
a distributed heating source for establishing substantially uniform heat throughout a process zone within the process chamber during thermal processing;
a gas injector having a plurality of gas injector ports generally disposed in proximity to the processing zone; and
a gas exhaust having a plurality of gas exhaust ports generally disposed in proximity to the processing zone, in opposition to the gas injection ports across the processing zone.

29. A method for thermally processing a plurality of substrates held on a carrier within a process zone of a process chamber having a top wall, a side wall, and a bottom wall, the method comprising steps of:
heating the process zone from a heat source having a plurality of heating elements, each of the plurality of heating elements disposed proximate to at least one of the top wall, the side wall and the bottom wall of the process chamber;
inserting the carrier with the plurality of substrates held therein into the process zone; and
introducing a fluid on one side of the plurality of substrates through a plurality of injection ports positioned relative to the plurality of substrates held in the carrier; and
flowing the fluid across surfaces of the plurality of substrates from the plurality of injection ports to a plurality of exhaust ports in a liner separating the carrier with the plurality of substrates held therein from the top wall and the side wall of the process chamber, the exhaust ports positioned relative to the plurality of substrates held in the carrier.

30. A method according to claim 29, wherein the bottom of the process chamber comprises a pedestal having at least one of the plurality of heating elements therein, the pedestal adapted to be lowered and raised to enable the batch of substrates in the carrier to be inserted into the process chamber, and wherein the step of inserting the carrier with the plurality of substrates held therein into the process zone comprises the steps of:
positioning the carrier on the pedestal; and
raising the pedestal to insert the carrier with the plurality of substrates held therein into the process zone.

31. A method according to claim 30, wherein the step of raising the pedestal to insert the carrier with the plurality of substrates held therein into the process zone comprises the step of simultaneously preheating the plurality of substrates in the carrier to an intermediate temperature.

32. A method according to claim 30, wherein the pedestal comprises a removable shield capable of reflecting heat from the at least one of the plurality of heating elements back to the pedestal to maintain the temperature thereof, and wherein the method further comprises the step of prior to inserting the carrier with the plurality of substrates held therein into the process chamber moving the removable shield into a position to reflect heat from the at least one of the plurality of heating elements back to the pedestal to maintain the temperature thereof.

33. A method according to claim 30, wherein the apparatus further comprises a shutter adapted to be moved into place above the carrier to isolate the process chamber when the pedestal is in a lowered position, and wherein the method further comprises the step of moving the shutter carrier to isolate the process chamber and maintain the temperature thereof when the pedestal is in the lowered position.

34. A method according to claim 30, wherein the apparatus further comprises a magnetically coupled repositioning system adapted to reposition the carrier with the plurality of substrates held therein during thermal processing of the plurality of substrates, and wherein the method further comprises the step of magnetically coupling mechanical energy through the pedestal to the carrier to reposition the carrier during thermal processing of the plurality of substrates without use of a movable feedthrough into the process chamber, and substantially without moving the at least one of the plurality of heating elements in the pedestal.
a plurality of substrates held on a carrier within a process zone of a process chamber having a top wall, a side wall, and a bottom wall,

35. A method of reconfiguring an apparatus for thermally processing a plurality of substrates held on a carrier within a process zone of a process chamber defined by a process vessel and a base-plate, apparatus further including a first injector having at least one injector port positioned in a first position relative to the plurality of substrates held on the carrier through which a fluid is introduced to process the plurality of substrates, and a first liner separating the at least one injector and the carrier with the plurality of substrates held therein from the process vessel, the liner having at least one exhaust port positioned in a first position relative to the plurality of substrates held on the carrier, the method comprising steps of:
separating the process vessel and the base-plate;
removing the first injector from the process chamber;
removing the first liner from the process chamber;
installing a second liner having at least one exhaust port in the process chamber;
installing a second injector having at least one injector port in the process chamber; and
wherein the second injector and second liner have at least one injector port and exhaust port positioned in a different position relative to the plurality of substrates held on the carrier than the first injector and the first liner.

36. A method according to claim 35, wherein the first injector is integrally formed with the first liner, and wherein the step of removing the first injector from the process chamber also comprises the step of removing the first liner from the process chamber.

37. A method according to claim 35, wherein the second injector is integrally formed with the second liner, and wherein the step of installing the second injector in the process chamber also comprises the step of installing the second liner in the process chamber.

38. A method according to claim 35, wherein the steps of installing the second injector in the process chamber and installing the second liner in the process chamber, comprise the steps of steps of installing the second injector in the process chamber and installing the second liner in the process chamber to provide a flow pattern selected from the group consisting of:
up-flow;
down-flow; and
cross-flow.

39. An apparatus for thermally processing a plurality of substrates held within a process zone in a carrier, the carrier with the substrates held therein being of a predetermined shape and volume, comprising:
a process chamber enclosure, the interior thereof defining a thermal process chamber, and the process zone being contained within the process chamber; and
a heating source distributed substantially throughout the interior of the process chamber enclosure for establishing a substantially isothermal environment in the process zone;
wherein the process chamber interior is generally conformal with the predetermined shape; and
wherein the process chamber is of a volume generally commensurate with the predetermined volume.

40. An apparatus for thermally processing a plurality of substrates held in a carrier, the apparatus comprising:
a process chamber having a top wall, a side wall and a bottom wall;
a heating source having a plurality of heating elements proximal to the top wall, the side wall and the bottom wall of the process chamber to provide a substantially isothermal environment in a process zone in which the carrier with the plurality of substrates held therein is positioned to thermally process the plurality of substrates; and
wherein the process chamber comprises dimensions selected to enclose a volume substantially no larger than a volume necessary to accommodate the carrier with the plurality of substrates held therein.

41. An apparatus according to claim 40, wherein the process chamber comprises dimensions selected to enclose a volume substantially no larger than 125% of the volume necessary to accommodate the carrier with the plurality of substrates held therein.

42. An apparatus according to claim 40, further comprising a controller capable of independently adjusting power to at least one of the plurality of heating elements to provide the substantially isothermal environment in the process zone.

43. An apparatus according to claim 40, wherein the bottom wall of the process chamber comprises a movable pedestal having at least one of the plurality of heating elements therein, the movable pedestal adapted to be lowered and raised to enable the carrier with the plurality of substrates held therein to be inserted into and removed from the process chamber.

44. An apparatus according to claim 40, wherein the heating source is adapted to provide a substantially isothermal environment in the process zone without the use of guard heaters proximal to the side wall of the process chamber above and below the process zone.

45. A method for thermally processing a plurality of substrates held within a process zone in a carrier, the carrier with the substrates held therein being of a predetermined shape and volume, comprising:
introducing the carrier with the substrates held therein into a process chamber enclosure having an interior that is generally conformal with the predetermined shape and that contains a volume generally commensurate with the predetermined volume; and
applying heat to the substrates from throughout the interior of the process chamber enclosure;
wherein the substrates are maintained at substantially identical temperatures.

46. A method for thermally processing a plurality of substrates held on a carrier, the method comprising steps of:
inserting the carrier with the plurality of substrates held therein into a process chamber having a top wall, a side wall and a bottom wall, the process chamber having a volume not substantially larger than necessary to accommodate the carrier with the plurality of substrates held therein; and
heating the process chamber from a heat source having a plurality of heating elements, each of the plurality of heating elements disposed proximate to at least one of the top wall, the side wall and the bottom wall of the process chamber, to provide a substantially isothermal environment at a desired temperature in a process zone in the process chamber,
whereby each substrate of the plurality of substrates is quickly and uniformly heated to the desired temperature.

47. A method according to claim 46, wherein the bottom of the process chamber comprises a pedestal having at least one of the plurality of heating elements therein, the pedestal adapted to be lowered and raised to enable the batch of substrates in the carrier to be inserted into the process chamber, and wherein the step of inserting the carrier with the plurality of substrates held therein into the process chamber comprises the steps of:
positioning the carrier on the pedestal; and
raising the pedestal to insert the carrier with the plurality of substrates held therein into the process chamber while simultaneously preheating the plurality of substrates in the carrier to an intermediate temperature.

48. A method according to claim 46, wherein the step of heating the process chamber comprises the step of independently adjusting power to at least one of the plurality of heating elements to provide a substantially isothermal environment in the process zone.

49. A method according to claim 46, further comprising the steps of while continuing to heat the process chamber using the heat source to maintain a substantially isothermal environment at the desired temperature in the process zone:
removing the carrier with the batch of substrates therein from the process chamber when the batch of substrates has been thermally processed; and
inserting another batch of substrates in another carrier into the process chamber to thermally process the batch of substrates,
whereby each substrate of each batch of substrates is quickly and uniformly heated to and processed at the desired temperature.
